(19) United States
(12) Patent Application Publication
(10) Pub. No.: US 2007/0235878 A1
(43) Pub. Date: Oct. 11, 2007

(54) INTEGRATED CIRCUIT PACKAGE SYSTEM WITH POST-PASSIVATION INTERCONNECTION AND INTEGRATION

(75) Inventors: Yaojian Lin, Singapore (SG); Pandi Chelvam Marimuthu, Singapore (SG)

Correspondence Address: ISHIMARU & ZAHRT LLP, 333 W. EL CAMINO REAL, SUITE 330, SUNNYVALE, CA, 94087, US

(73) Assignee: STATS ChipPAC Ltd., Singapore (SG)

(21) Appl. No.: 11/278,002

(22) Filed: Mar. 30, 2006

(51) Int. Cl. H01L 23/48

(52) U.S. Cl. 257/773

(57) ABSTRACT

An integrated circuit package system is provided providing an integrated circuit die having a final metal layer of the semiconductor process used to manufacture the integrated circuit die and a passivation layer provided thereon, depositing a first metal layer on the passivation layer and the final metal layer, forming an analog circuit in the first metal layer, coating a first insulation layer on the first metal layer and the passivation layer, exposing a first pad and a second pad of the first metal layer through the first insulation layer, and connecting a first interconnect on the first pad and a second interconnect on the second pad.

### TECHNICAL FIELD

The present invention relates generally to integrated circuits and more particularly to integrated circuit packaging.

### BACKGROUND ART

Modern consumer electronics, such as smart phones, personal digital assistants, and location based services devices, as well as enterprise electronics, such as servers and storage arrays, are packing more integrated circuits into an ever shrinking physical space with expectations for decreasing cost. Every new generation of integrated circuits with increased operating frequency, performance and the higher level of large scale integration have underscored the need for back-end semiconductor manufacturing to provide more solutions involving the integrated circuit itself. Numerous technologies have been developed to meet these requirements. Some of the research and development strategies focus on new package technologies while others focus on improving the existing and mature package technologies. Both approaches may include additional processing of the integrated circuits to better match the targeted package.

The continued emphasis in the semiconductor technology is to create improved performance semiconductor devices at competitive prices. This emphasis over the years has resulted in extreme miniaturization of semiconductor devices, made possible by continued advances of semiconductor processes and materials in combination with new and sophisticated device designs. Numerous integrated circuit designs are aimed for mixed-signal designs by incorporating analog functions. One of the major challenges in the creation of analog processing circuitry (using digital processing procedures and equipment) is that a number of the components that are used for analog circuitry are large in size and are therefore not readily integrated into integrated circuits. The main components that offer a challenge in this respect are capacitors and inductors, since both these components are, for typical analog processing circuits, of considerable size. In response to the demands for improved package performance and analog circuitry integration, packaging manufacturers may prepare the integrated circuit for packaging as well as provide analog circuitry integration onto the integrated circuit.

With the rapid migration of on-chip interconnect from aluminum (Al) to copper (Cu), the demand for off-chip interconnects is increasing. The conventional gold wire bonding technologies are facing challenges with bare copper pads because pad oxidation inhibits a mature bonding process.

Thus, a need still remains for an integrated circuit package system with post-passivation interconnection and integration providing low cost manufacturing, improved yields, reduce the integrated circuit package dimensions, and provide flexible connectivity and integration configurations. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system including providing an integrated circuit die having a final metal layer of the semiconductor process used to manufacture the integrated circuit die and a passivation layer provided thereon, depositing a first metal layer on the passivation layer and the final metal layer, forming an analog circuit in the first metal layer, coating a first insulation layer on the first metal layer and the passivation layer, exposing a first pad and a second pad of the first metal layer through the first insulation layer, and connecting a first interconnect on the first pad and a second interconnect on the second pad.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of a first integrated circuit package system with post-passivation interconnection and integration in an embodiment of the present invention;

FIG. 2 is a cross-sectional view of a second integrated circuit package system with post-passivation interconnection and integration in an alternative embodiment of the present invention;

FIG. 3 is a cross-sectional view of a third integrated circuit package system with post-passivation interconnection and integration in another alternative embodiment of the present invention;

FIG. 4 is a cross-sectional view of a wafer structure in a first metallization phase in an embodiment of the present invention;

FIG. 5 is the structure of FIG. 4 in a first insulation phase;

FIG. 6 is the structure of FIG. 5 in a second metallization phase;

FIG. 7 is the structure of FIG. 6 in a second insulation phase;

FIG. 8 is the structure of FIG. 7 in a singulation phase; and

FIG. 9 is a flow chart of an integrated circuit package system with post-passivation interconnection and integration for manufacture of the integrated circuit package system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. The same numbers are used in all the figures to relate to the same elements.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

The term “processing” as used herein includes deposition of material, patterning, exposure, development, etching, cleaning, molding, and/or removal of the material or as required in forming a described structure.

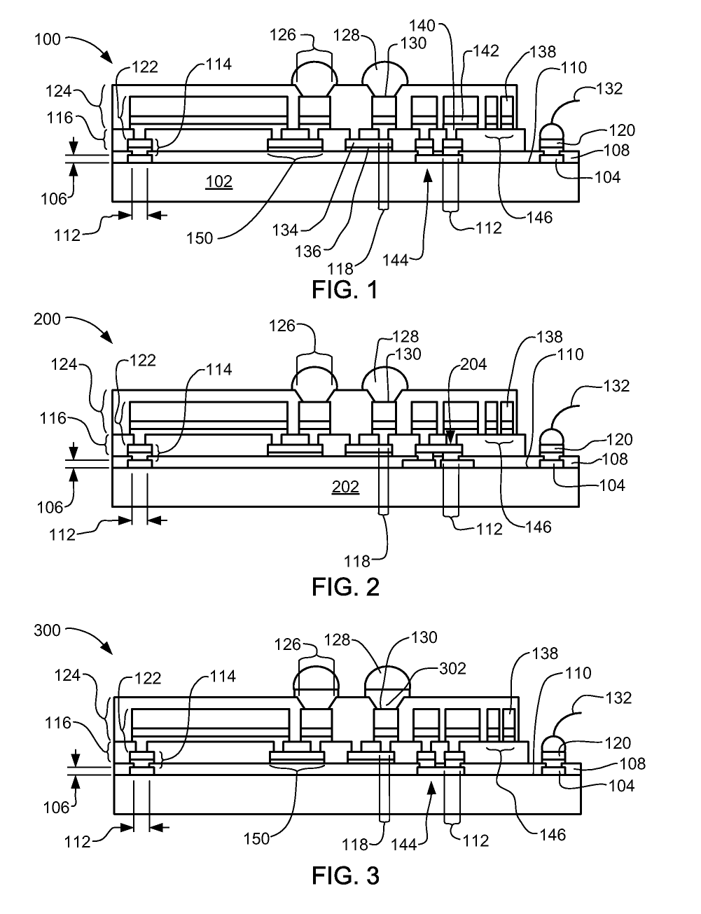

Referring now to FIG. 1, therein is shown a cross-sectional view of a first integrated circuit package system 100 with post-passivation interconnection and integration in an embodiment of the present invention. The first integrated circuit package system 100 includes an integrated circuit die 102 having bond pads 104, such as input/output (IO) pads, provided thereon. The bond pads 104 may be formed from a final metal layer 106 of the semiconductor process used to manufacture the integrated circuit die 102. The bond pads 104 may be formed by a number of metals, such as aluminum (Al), copper (Cu), or alloys.

A passivation layer 108 covers an active side 110 of the integrated circuit die 102 and provides passivation openings 112 exposing the bond pads 104. The passivation layer 108 is used to protect the underlying devices, such as transistors (not shown) or polysilicon passive circuit element structures (not shown) from penetration of mobile ions, moisture, transition metal (such as gold or silver), and other contaminations. For example, the passivation layer 108 may be a composite of oxide and nitride.

A first metal layer 114, such as a post-passivation metal one (M1) layer, is on the bond pads 104 in the passivation openings 112 and patterned on the passivation layer 108. A first insulation layer 116 is patterned and partially covers the passivation layer 108 if wire bonding is required, otherwise the first insulation layer 116 fully covers the passivation layer 108, and the first metal layer 114. First openings 118 in the first insulation layer 116 exposes the first metal layer 114 at predetermined locations. Predetermined locations of the first metal layer 114 are not covered or surrounded by the first insulation layer 116 providing protective pads 120 for the bond pads 104. A second metal layer 122 is patterned on the first metal layer 114 in the first openings 118 and on the first insulation layer 116. A second insulation layer 124 covers the first insulation layer 116 and partially covers the second metal layer 122. Second openings 126 in the second insulation layer 124 expose the second metal layer 122 at predetermined locations.

First interconnects 128, such bumps or solder balls, are on the second metal layer 122 through the second openings 126, wherein the second metal layer 122 in the second openings 126 are bump pads 130. Second interconnects 132, such as bond wires, are on the protective pads 120 of the first metal layer 114. Both the first interconnects 128 and the second interconnects 132 may be used for electrical connections to the integrated circuit die 102.

The first metal layer 114 may be a stack of different metals or alloys. The stack may include a first top layer 134, such as a top metal layer, and optionally a first bottom layer 136, such as an adhesion or barrier layer. The first bottom layer 136 may be made from a number of metals or alloys, such as tin (Ti), tin tungsten (TiW), tin nitride (TiN), tantalum (Ta), or tantalum nitride (TaN), with TiW preferred due to its selectivity in the process. The first bottom layer 136 may have a thickness in the range from 200 A to 2000 A. The first top layer 134 may be made from a number of metals and alloys, such as aluminum (Al), Al alloy, gold (Au), or copper (Cu), with a thickness in the range from 1.0 μm to 10.0 μm. Copper is preferred if wire bonding is not required otherwise Al alloy, such as AlCu0.5, is preferred with typical thickness of 1.5 μm.

The first insulation layer 116 may be made from a number of materials, such as polyimide, benzocyclobutene (BCB), polybenzoxazole (PBO), or laminated solder dry film. A typical thickness of the first insulation layer 116 is approximately 5 μm.

The second metal layer 122 may be a stack of different metal or alloys. The stack may include a second top layer 138, a second bottom layer 140, such as an adhesion layer, and optionally a middle layer 142, such as a barrier layer. The second bottom layer 140 may be made from a number of metals or alloys, such as chromium (Cr), Ti, TiW, or Ta, and is typically Ti. If the first top layer 134 is Al or Al alloy then the second bottom layer 140 may be Al. The thickness of the second bottom layer 140 is in the range from 200 A to 1000 A. The middle layer 142 may be made from a number of metals or alloys, such as nickel vanadium (NiV), CrCu, TiW, or TaN, and is typically NiV. The thickness of the middle layer 142 is in the range from 500 A to 3000 A. The second top layer 138 may be made from a number of metals or alloys, such as Cu, with a thickness in the range from 5 μm to 12 μm.

The second insulation layer 124 may be made from a number of materials, such as polyimide, benzocyclobutene (BCB), polybenzoxazole (PBO), or other polymers. A typical thickness of the second insulation layer 124 is in the range from 8 μm to 16 μm.

The final metal layer 106 of the integrated circuit die 102 may provide a first analog circuit bridge 144 for the wings of an analog circuit 146, such as an inductor. The first metal layer 114 in the passivation openings 112 provides metal caps protecting the bond pads 104 from environmental damage, such as oxidation from ambient, and from further connections, such as wire bonding. The first metal layer 114 also serves as a first metal bridge 150 between the bump pads 130 and the other portions of the second metal layer 122 serving as redistribution layer (RDL).

The first insulation layer 116 serves as a stress buffer or protective coat for the integrated circuit die 102. The first insulation layer 116 separates the analog circuit 146, such as the inductor, in the second metal layer 122 from the substrate of the integrated circuit die 102 resulting in an increase in the Q value of the inductor.

The second metal layer 122 provides a redistribution layer and integrates the analog circuit 146. The second metal layer 122 also provides the bump pads 130 that stand alone for the first interconnects 128. The stand-alone and near symmetric configuration prevents non-uniform or non-symmetric stress distribution at the bump pads 130 and subsequently to the integrated circuit die 102. Instead, the stand-alone configuration allows the stress to be distributed symmetrically.

The second insulation layer 124 serves as a stress buffer or protective coat for the second metal layer 122. The second insulation layer 124 in conjunction with the first insulation layer 116 jointly protects the post-passivation stack of the first metal layer 114 and the second metal layer 122 as well as the integrated circuit die 102.

Referring now to FIG. 2, therein is shown a cross-sectional view of a second integrated circuit package system 200 with post-passivation interconnection and integration in an alternative embodiment of the present invention. The second integrated circuit package system 200 includes an integrated circuit die 202 having the bond pads 104 formed from the final metal layer 106. The passivation layer 108 covers the active side 110 of the integrated circuit die 202 and exposes the bond pads 104 through the passivation openings 112.

Similarly, the first metal layer 114 is patterned and on the bond pads 104 through the passivation openings 112 as well as on the passivation layer 108. The first insulation layer 116 partially covers the passivation layer 108 if wire bonding is required, otherwise the first insulation layer 116 fully covers the passivation layer 108, and the first metal layer 114 with the first openings 118 exposing the first metal layer 114. Predetermined locations of the first metal layer 114 are the protective pads 120 not covered or surrounded by the first insulation layer 116. The second metal layer 122 is on the first metal layer 114 in the first openings 118 and on the first insulation layer 116, both at predetermined locations. The second insulation layer 124 covers the first insulation layer 116 and partially covers the second metal layer 122 with the second openings 126 exposing the second metal layer 122. The locations of the second top layer 138 exposed by the second openings 126 are the bump pads 130. The first interconnects 128 are attached to the bump pads 130. The second interconnects 132 are attached to the protective pads 120.

The second integrated circuit package system 200 also provides a portion of the first metal layer 114 as a second analog circuit bridge 204 for the wings of the analog circuit 146 provided in the second metal layer 122. The second analog circuit bridge 204 connects two instances of the bond pads 104.

Referring now to FIG. 3, therein is shown a cross-sectional view of a third integrated circuit package system 300 with post-passivation interconnection and integration in another alternative embodiment of the present invention. Similarly, the third integrated circuit package system 300 includes the integrated circuit die 102 having the bond pads 104 formed from the final metal layer 106. The final metal layer 106 provides the first analog circuit bridge 144 for the wings of the analog circuit 146 provided in the second metal layer 122. The passivation layer 108 covers the active side 110 of the integrated circuit die 102 and exposes the bond pads 104 through the passivation openings 112.

The first metal layer 114 is patterned and on the bond pads 104 through the passivation openings 112 as well as on the passivation layer 108. The first insulation layer 116 partially covers the passivation layer 108 if wire bonding is required, otherwise the first insulation layer 116 fully covers the passivation layer 108, and the first metal layer 114 with the first openings 118 exposing the first metal layer 114. Predetermined locations of the first metal layer 114 are the protective pads 120 not covered or surrounded by the first insulation layer 116. The second metal layer 122 is on the first metal layer 114 in the first openings 118 and on the first insulation layer 116, both at predetermined locations. The second insulation layer 124 covers the first insulation layer 116 and partially covers the second metal layer 122 with the second openings 126 exposing the second metal layer 122. The locations of the second top layer 138 exposed by the second openings 126 are the bump pads 130. The second interconnects 132 are attached to the protective pads 120.

The third integrated circuit package system 300 also includes a standard UBM 302 made from a number of metals or alloys, such as Ti, NiV, or Cu, for the first interconnects 128. The first metal bridge 150 is optional in the third integrated circuit package system 300.

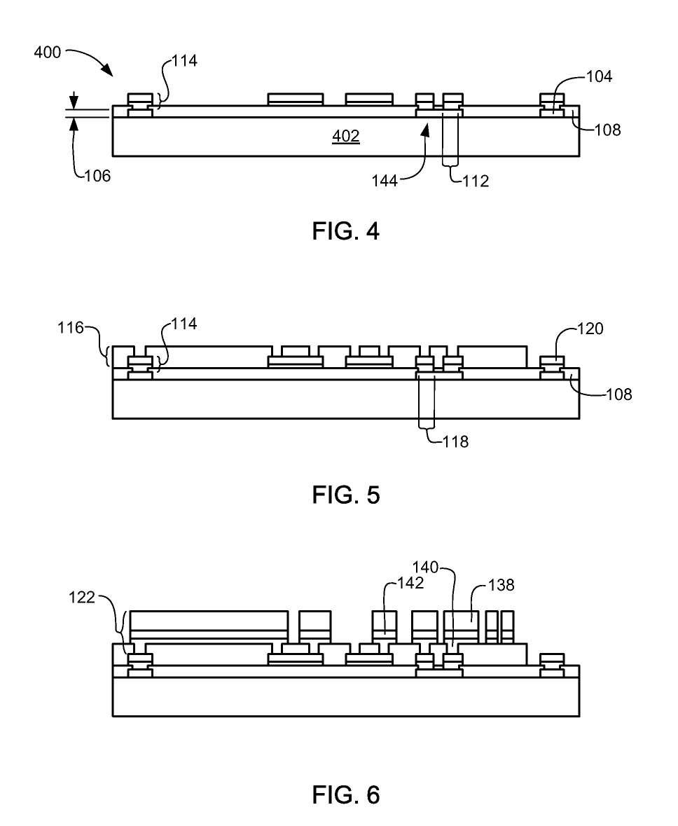

Referring now to FIG. 4, therein is shown a cross-sectional view of a wafer structure 400 in a first metallization phase in an embodiment of the present invention. The wafer structure 400 includes a wafer 402 having the final metal layer 106 and the passivation layer 108 provided thereon. The final metal layer 106 forms the bond pads 104 and the first analog circuit bridge 144. The passivation openings 112 expose the bond pads 104 through the passivation layer 108.

The first metal layer 114 is applied onto the wafer structure 400 using any number of methods, such as sputtering or plating. The first metal layer 114 is patterned using photoresist and etching, although other methods may be used. The photoresist is removed for further processing.

Referring now to FIG. 5, therein is shown the structure of FIG. 4 in a first insulation phase. The first insulation layer 116 is applied onto the structure of FIG. 4 with spin coating, although other methods may be used. Patterns on the first insulation layer 116 may be formed with a number of processes, such as dry etch, wet etch, or dry etch with laser ablation. The patterns include the first openings 118 in the first insulation layer 116 exposing the first metal layer 114 and removal of the first insulation layer 116 exposing the protective pads 120 as well as the passivation layer 108. The first insulation layer 116 may undergo curing.

Referring now to FIG. 6, therein is shown the structure of FIG. 5 in a second metallization phase. The second metal layer 122 is formed on the structure of FIG. 5. The second bottom layer 140, such as the adhesion layer, may be deposited. The middle layer 142 may optionally be deposited on the second bottom layer 140. Copper plating seed layer may be sputtered on the second bottom layer 140 or optionally on the middle layer 142. A thick photoresist is spin coated and patterned for the selective Cu plating. The second top layer 138 is electroplated to the desired thickness. The photoresist is removed by etching. The second bottom layer 140, the second top layer 138, and optionally the middle layer 142 are wet etched forming the pattern of the second metal layer 122. The portions of the second bottom layer 140 and the middle layer 142 covered by the second top layer 138 remains while portions not covered are etched away.

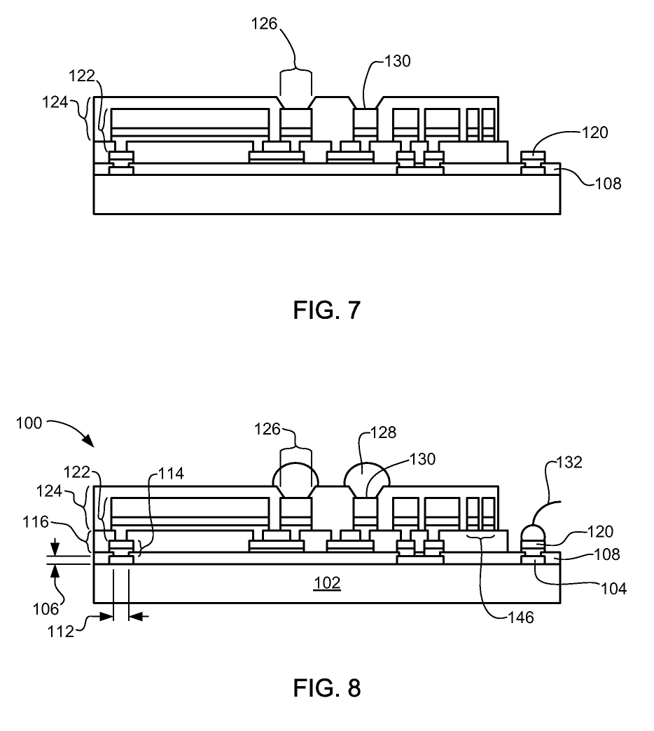

Referring now to FIG. 7, therein is shown the structure of FIG. 6 in a second insulation phase. The second insulation layer 124 is spin coated onto the structure of FIG. 6. Patterns on the second insulation layer 124 may be formed with a number of processes, such as dry etch, wet etch, or dry etch with laser ablation. The patterns include the second openings 126 in the second insulation layer 124 forming the bump pads 130 of the second metal layer 122 and removal of the second insulation layer 124 exposing the protective pads 120 as well as the passivation layer 108. The second insulation layer 124 may undergo curing.

Referring now to FIG. 8, therein is shown the structure of FIG. 7 in a singulation phase. The first interconnects 128 are formed and attached on the bump pads 130 in the second openings 126. The wafer 402 of FIG. 4having the final metal layer 106, the passivation layer 108, the first metal layer 114, the first insulation layer 116, the second metal layer 122, and the second insulation layer 124, the first interconnects 128 attached to the bump pads 130, and the protective pads 120 exposed undergo singulation forming the integrated circuit die 102 with the post-passivation stack described. The second interconnects 132 are attached to the protective pads 120 forming the first integrated circuit package system 100 with post-passivation interconnection and integration.

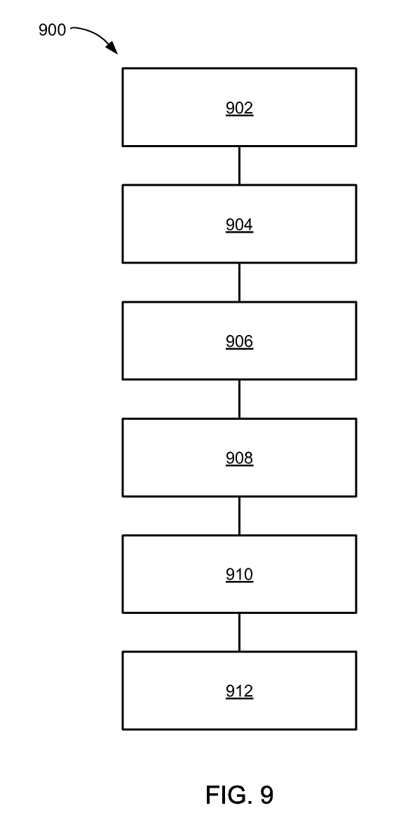

Referring now to FIG. 9, therein is shown a flow chart of an integrated circuit package system 900 with post-passivation interconnection and integration for manufacture of the integrated circuit package system 100 in an embodiment of the present invention. The system 900 includes providing an integrated circuit die having a final metal layer of the semiconductor process used to manufacture the integrated circuit die and a passivation layer provided thereon in a block 902; depositing a first metal layer on the passivation layer and the final metal layer in a block 904; forming an analog circuit in the first metal layer in a block 906; coating a first insulation layer on the first metal layer and the passivation layer in a block 908; exposing a first pad and a second pad of the first metal layer through the first insulation layer in a block 910; and connecting a first interconnect on the first pad and a second interconnect on the second pad in a block 912.

It has been discovered that the present invention thus has numerous aspects.

It has been discovered that the present invention provides flexibility for different electrical interconnect types, such as solder balls with bond wires, increasing the flexibility of increased input/output count, stacking, and packaging options for the integrated circuit die in an embodiment of the present invention. The post-passivation interconnection types and analog circuit integration lowers parasitics to enhance the integrated circuit die performance, and facilitate system-on-a-chip (SOC) and system-in-a-package (SIP) design with post-passivation passive structures.

An aspect is that the present invention provides features for improved manufacturing yield and lower cost. The stand alone and near symmetric copper pads for the solder balls prevent non-uniform or non-symmetric stress on the integrated circuit die to mitigate damage. The under ball metallization (UBM) is not required for the solder balls reducing the manufacturing steps to provide improved yields and lowers cost. The analog circuit integration in the post-passivation stack does not take up space on the integrated circuit die to reduce design complexity and reduces cost. The UBM for the solder ball is optional and may further reduce the cost of the integrated circuit die.

Another aspect of the present invention is the first metal layer (M1) protects the bond pads (IO pad) of the integrated circuit die from the etching process of the optional adhesion layer, the first bottom layer. The first metal layer may provide bridges for redistribution layer from the second metal layer and for the inductors in the second metal layer. The first metal layer also protects the bond pad during the wire bonding process. The final metal layer of the integrated circuit die may be used for bond pads or to bridge the inductor in the second metal layer.

Yet another aspect of the present invention is that the flexibility for higher IO count, stacking configurations, and packaging configurations may be used for copper final metal layer and second metal layers or with other metals and alloys. The different interconnect types, such as solder balls and bond wires, allows for additional flexibility to connect crucial signal(s) closer or farther away from the analog circuit, the inductor, in the post-passivation stack. This flexibility provides improved performance and electrical isolation. Both solder bumping and wire bonding may be supported without a gold layer thereby eliminating the need for a gold plating tool to further simplify the manufacturing process and reduce cost.

Yet another important aspect of the present invention is that it valuably supports and services the historical trend of reducing costs and increasing performance. These and other valuable aspects of the present invention consequently further the state of the technology to at least the next level.

Thus, it has been discovered that the integrated circuit package system with post-passivation interconnections and integration method of the present invention furnishes important and heretofore unknown and unavailable solutions, capabilities, and functional aspects for increasing chip density while minimizing the space required in systems. The resulting processes and configurations are straightforward, cost-effective, uncomplicated, highly versatile and effective, can be implemented by adapting known technologies, and are thus readily suited for efficiently and economically manufacturing stacked integrated circuit packaged devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

1. An integrated circuit package system comprising:
providing an integrated circuit die having a final metal layer of the semiconductor process used to manufacture the integrated circuit die and a passivation layer provided thereon;
depositing a first metal layer on the passivation layer and the final metal layer;
forming an analog circuit with the final metal layer;
coating a first insulation layer on the first metal layer and the passivation layer;
exposing a first pad and a second pad of the first metal layer through the first insulation layer; and
connecting a first interconnect on the first pad and a second interconnect on the second pad.

2. The system as claimed in claim 1 further comprising forming a bridge with the final metal layer for the analog circuit.

3. The system as claimed in claim 1 further comprising forming a bridge with the first metal layer for the analog circuit.

4. The system as claimed in claim 1 further comprising forming an under bump metallization on the first pad.

5. The system as claimed in claim 1 wherein depositing the first metal layer comprises forming a stack of layers of different metals or alloys.

6. An integrated circuit package system comprising:
providing an integrated circuit die having a final metal layer of the semiconductor process used to manufacture the integrated circuit die and a passivation layer provided thereon;
forming an analog circuit with the final metal layer:
depositing a first metal layer on the passivation layer and the final metal layer;
coating a first insulation layer on the first metal layer and the passivation layer;
depositing a second metal layer on the first insulation layer and the first metal layer;
coating a second insulation layer on the second metal layer;
exposing a protective pad of the first metal layer;
exposing a bump pad of the second metal layer through the second insulation layer; and
connecting a bond wire on the protective pad and a solder ball on the bump pad.

7. The system as claimed in claim 6 wherein forming the analog circuit comprises forming a passive analog circuit element.

8. The system as claimed in claim 6 further comprising forming a bridge with the first metal layer for the analog circuit.

9. The system as claimed in claim 6 further comprising forming a bridge with the first metal layer for the second metal layer.

10. The system as claimed in claim 6 wherein depositing the second metal layer comprises forming a stack of layers of different metals or alloys.

11. An integrated circuit package system comprising:
an integrated circuit die having a final metal layer of the semiconductor process used to manufacture the integrated circuit die and a passivation layer provided thereon;
a first metal layer on the passivation layer and the final metal layer;
an analog circuit with the final metal layer;
a first insulation layer on the first metal layer and the passivation layer;
a first pad and a second pad of the first metal layer exposed through the first insulation layer; and
a first interconnect on the first pad and a second interconnect on the second pad.

12. The system as claimed in claim 11 further comprising a bridge with the final metal layer for the analog circuit.

13. The system as claimed in claim 11 further comprising a bridge with the first metal layer for the analog circuit.

14. The system as claimed in claim 11 further comprising an under bump metallization on the first pad.

15. The system as claimed in claim 11 wherein the first metal layer includes a stack of layers of different metals or alloys.

16. The system as claimed in claim 11 wherein:
the integrated circuit die having the final metal layer of the semiconductor process used to manufacture the integrated circuit die and the passivation layer provided thereon has an active side;
the first metal layer on the passivation layer and the final metal layer is a redistribution layer;
the first insulation layer on the first metal layer and the passivation layer is made of a polymer;
the first pad of the first metal layer exposed is a protective pad; and
the first interconnect on the first pad is a bond wire; and further comprising:
a second metal layer on the first insulation layer and the first metal layer;
a second insulation layer on the second metal layer;
the analog circuit in the second metal layer;
exposing a bump pad of the second metal layer through the second insulation layer; and
a solder ball on the bump pad.

17. The system as claimed in claim 16 wherein the analog circuit is a passive analog circuit element.

18. The system as claimed in claim 16 further comprising a bridge with the first metal layer for the analog circuit.

19. The system as claimed in claim 16 further comprising a bridge with the first metal layer for the second metal layer.

20. The system as claimed in claim 16 wherein the second metal layer comprises a stack of layers of different metals or alloys.
